(19) United States
(12) Patent Application Publication
(10) Pub. No.: US 2022/0310461 A1
(43) Pub. Date: Sep. 29, 2022

(54) IN-WAFER TESTING DEVICE

(71) Applicant: Alfasemi Inc., Taipei City (TW)

(72) Inventors: Te-Lung SHIH, Taipei City (TW); Chao-Feng HSU, New Taipei City (TW)

(21) Appl. No.: 17/210,550

(22) Filed: Mar. 24, 2021

(51) Int. Cl. H01L 21/66; G01R 31/28

(52) U.S. Cl. CPC H01L 22/34; G01R 31/2831

(57) ABSTRACT

An in-wafer testing device for a wafer apparatus includes a testing wafer and a testing circuit. The testing wafer is adapted to be put into the wafer apparatus. The testing circuit is integrated in the testing wafer, and configured to measure one or more properties of the wafer apparatus.

### BACKGROUND OF THE INVENTION

### 1. Field of the Invention

The present invention relates to an in-wafer testing device for a semiconductor apparatus.

### 2. Description of Related Art

A semiconductor apparatus is an apparatus to perform semiconductor device fabrication on wafers, and it typically forms integrated circuits on the wafers. A semiconductor manufacturing process includes a series of photolithographic and chemical processing steps. Silicon is the most commonly used semiconductor material, but there are still various other compound semiconductor materials that can be used.

Various semiconductor apparatuses have been developed for different purpose, for example, wafer processing, die preparation, IC packaging, IC testing, and so on. A semiconductor apparatus requires periodic testing or special testing for troubleshooting, in those cases, the semiconductor apparatus has to be turned off, and it takes much time, usually about 24 hours, to restart the semiconductor apparatus, which causes the delay in the delivery date and the increase of the manufacturing cost.

In some cases, a vacuumed or purified semiconductor apparatus has to be opened so that some testing instruments can be put into it, but the semiconductor apparatus will lose its vacuum or purity, and it takes a lot of effort and time to vacuum or purify the semiconductor apparatus again.

The above problem becomes severer with the increase of the number of chambers in the semiconductor apparatus.

Therefore, it is desirable to provide an improved testing device to mitigate and/or obviate the aforementioned problems.

### SUMMARY OF THE INVENTION

One object of the present invention is to provide a testing device that can be used to test a wafer apparatus by measuring some properties of the wafer apparatus without turning off the wafer apparatus, so that the wafer apparatus can immediately return to work for manufacturing, processing, or testing a normal semiconductor wafer after the testing device of the present invention finishes the measurement.

Therefore, it is not necessary to wait the wafer apparatus to restart (or reboot) from complete shutdown, and it is not necessary to wait some restoring processes such as heating up, cooling down, vacuuming, or purifying, again to meet with the original conditions for the normal semiconductor wafer. It can be seen that the present invention is advantageous because it can save a lot of time, from hours to days.

Moreover, it is risky to open a vacuumed or purified wafer apparatus to put a detecting instrument into it because air and impurities may enter the vacuumed or purified wafer apparatus. However, using the testing device of the present invention, it is possible to perform a testing without opening the vacuumed or purified wafer apparatus. According to the present invention, it does not require the restoring processes that are harmful to the wafer apparatus, and the wafer apparatus can have a longer service life.

To achieve the object, the present invention provides an in-wafer testing device for a wafer apparatus, which includes a testing wafer and a testing circuit. The testing wafer is adapted to be put into the wafer apparatus. The testing circuit is integrated in the testing wafer, and configured to measure one or more properties of the wafer apparatus.

Optionally or preferably, the wafer apparatus is a manufacturing apparatus, a processing apparatus, or a testing apparatus, for a semiconductor wafer.

Optionally or preferably, the testing wafer is a dummy wafer that is not a material to form chip products.

Optionally or preferably, the wafer apparatus is measured with its power supply remaining turned on.

Optionally or preferably, the wafer apparatus is measured with its chamber remaining vacuumed or purified.

Optionally or preferably, wherein the testing wafer is put into the wafer apparatus after a normal semiconductor wafer is and before another normal semiconductor wafer is.

Optionally or preferably, a measurement by the testing circuit in the testing wafer is performed after a normal operation executed by the wafer apparatus for a normal semiconductor wafer and before another normal operation executed by the wafer apparatus for another normal semiconductor wafer.

Optionally or preferably, the one or more properties of the wafer apparatus measured by the testing circuit include a position, a shift, a path, a linear velocity, a linear acceleration, an angular velocity, an angular acceleration, a vibration, a temperature, an invisible light, and/or a humidity of a unit of the wafer apparatus. Moreover, the unit may be a robot arm, a support plate, a support frame, or a chamber of the wafer apparatus.

Optionally or preferably, the testing circuit includes a microprocessor configured to perform a measurement algorithm for obtaining the one or more properties of the wafer apparatus. Moreover, the testing circuit may include a wireless transceiver connected to the microprocessor. Furthermore, the wireless transceiver may be configured to communicate with a monitoring device for the wafer apparatus. Furthermore, the wireless transceiver may include an on-chip antenna.

Optionally or preferably, the testing circuit includes a position sensor, an orientation sensor, or a magnetometer, connected to the microprocessor.

Optionally or preferably, the testing circuit includes a motion sensor, an accelerometer, a gravity sensor, a gyroscope or a rotation vector sensor, connected to the microprocessor.

Optionally or preferably, the testing circuit includes an environmental sensor, a barometer, a photometer, or a thermometer, connected to the microprocessor.

Optionally or preferably, the testing wafer includes a top layer and a bottom layer in a stack, and the testing circuit is disposed between the top layer and the bottom layer. Moreover, a top recess may be formed in the top layer, a bottom recess may be formed in the bottom layer, and the testing circuit may be disposed between the top recess and the bottom recess.

Optionally or preferably, the testing wafer is formed with an optical marker, an electronic marker, a magnetic marker, or a physical marker on its surface so that the testing wafer is distinguishable from a normal semiconductor wafer. Moreover, the wafer apparatus includes an identifier used to identify the marker(s).

Optionally or preferably, the wafer apparatus is implemented as an unmanned transport vehicle (UTV), a floor traveling vehicle (FTV) including an automated guided vehicle (AGV) system or a rail guided vehicle (RGV) system, an overhead traveling vehicle (OTV) including an overhead shuttle (OHS) system or an overhead hoist transport (OHT) system.

Other objects, advantages, and novel features of the invention will become more apparent from the following detailed description when taken in conjunction with the accompanying drawings.

### BRIEF DESCRIPTION OF THE DRAWINGS

FIG. 1 shows an in-wafer testing device and a wafer apparatus according to one embodiment of the present invention;

FIG. 2 shows an in-wafer testing device and another wafer apparatus according to another embodiment of the present invention;

FIG. 3 shows a structural diagram of the testing wafer according to one embodiment of the present invention;

FIG. 4 shows a block diagram of the testing circuit according to one embodiment of the present invention; and

FIG. 5 shows a schematic diagram illustrating a testing procedure using the in-wafer testing device of the present invention.

### DETAILED DESCRIPTION OF THE EMBODIMENT

Different embodiments of the present invention are provided in the following description. These embodiments are meant to explain the technical content of the present invention, but not meant to limit the scope of the present invention. A feature described in an embodiment may be applied to other embodiments by suitable modification, substitution, combination, or separation.

It should be noted that, in the present specification, when a component is described to have an element, it means that the component may have one or more of the elements, and it does not mean that the component has only one of the element, except otherwise specified.

Moreover, in the present specification, the ordinal numbers, such as “first” or “second”, are used to distinguish a plurality of elements having the same name, and it does not means that there is essentially a level, a rank, an executing order, or an manufacturing order among the elements, except otherwise specified. A “first” element and a “second” element may exist together in the same component, or alternatively, they may exist in different components, respectively. The existence of an element described by a greater ordinal number does not essentially means the existent of another element described by a smaller ordinal number.

Moreover, in the present specification, the terms, such as “top”, “bottom”, “left”, “right”, “front”, “back”, or “middle”, as well as the terms, such as “on”, “above”, “under”, “below”, or “between”, are used to describe the relative positions among a plurality of elements, and the described relative positions may be interpreted to include their translation, rotation, or reflection.

Moreover, in the present specification, when an element is described to be arranged “on” another element, it does not essentially means that the elements contact the other element, except otherwise specified. Such interpretation is applied to other cases similar to the case of “on”.

Moreover, in the present specification, the terms, such as “preferably” or “advantageously”, are used to describe an optional or additional element or feature, and in other words, the element or the feature is not an essential element, and may be ignored in some embodiments.

Moreover, in the present specification, when an element is described to be “suitable for” or “adapted to” another element, the other element is an example or a reference helpful in imagination of properties or applications of the element, and the other element is not to be considered to form a part of a claimed subject matter; similarly, except otherwise specified; similarly, in the present specification, when an element is described to be “suitable for” or “adapted to” a configuration or an action, the description is made to focus on properties or applications of the element, and it does not essentially mean that the configuration has been set or the action has been performed, except otherwise specified.

Moreover, each component may be realized as a single circuit or an integrated circuit in suitable ways, and may include one or more active elements, such as transistors or logic gates, or one or more passive elements, such as resistors, capacitors, or inductors, but not limited thereto. Each component may be connected to each other in suitable ways, for example, by using one or more traces to form series connection or parallel connection, especially to satisfy the requirements of input terminal and output terminal. Furthermore, each component may allow transmitting or receiving input signals or output signals in sequence or in parallel. The aforementioned configurations may be realized depending on practical applications.

Moreover, in the present specification, the terms, such as “system”, “apparatus”, “device”, “module”, or “unit”, refer to an electronic element, or a digital circuit, an analogous circuit, or other general circuit, composed of a plurality of electronic elements, and there is not essentially a level or a rank among the aforementioned terms, except otherwise specified.

Moreover, in the present specification, two elements may be electrically connected to each other directly or indirectly, except otherwise specified. In an indirect connection, one or more elements, such as resistors, capacitors, or inductors may exist between the two elements. The electrical connection is used to send one or more signals, such as DC or AC currents or voltages, depending on practical applications.

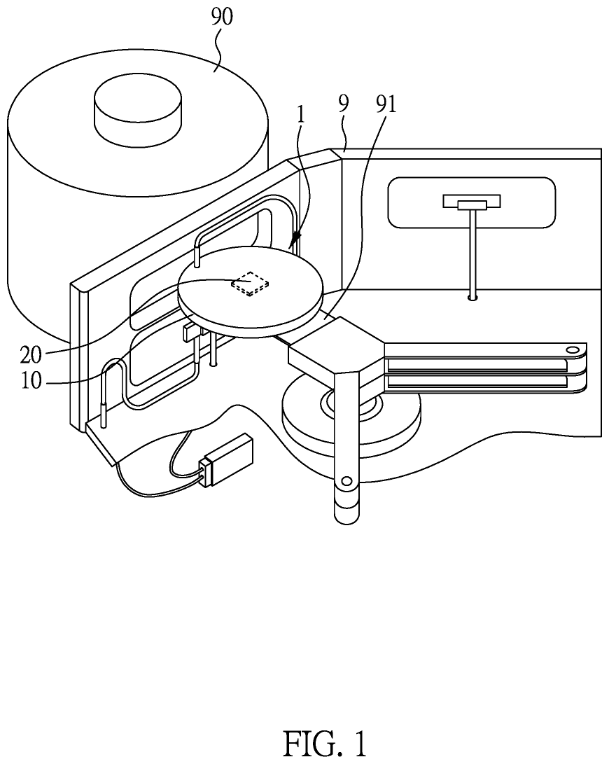

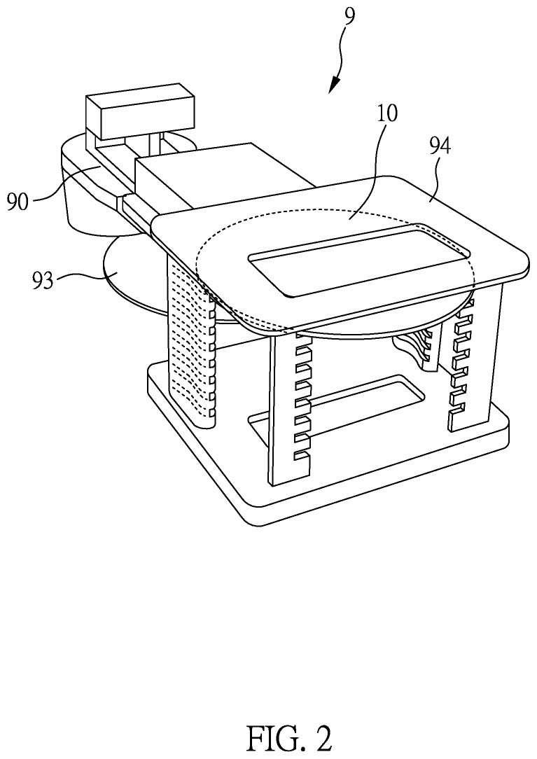

FIG. 1 shows an in-wafer testing device 1 and a wafer apparatus 9 according to one embodiment of the present invention. FIG. 2 shows an in-wafer testing device 1 and another wafer apparatus 9 according to another embodiment of the present invention.

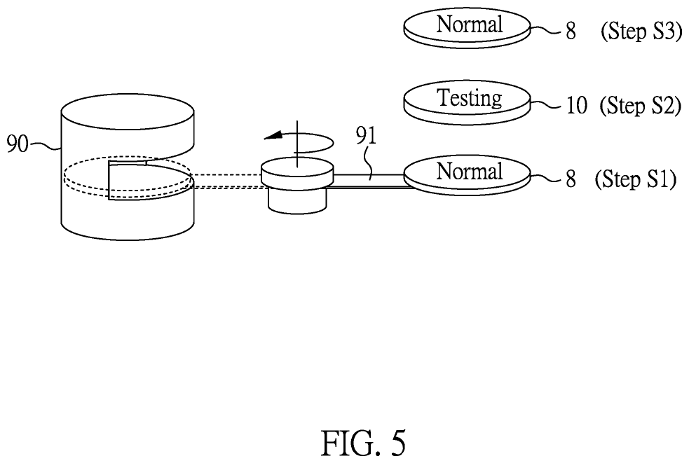

The in-wafer testing device 1 of the present invention essentially includes a testing wafer 10 and a testing circuit 20. The testing wafer 10 is adapted to be put into the wafer apparatus 9. The wafer apparatus 9 is a manufacturing apparatus, a processing apparatus, a testing apparatus, or any other apparatus for a semiconductor wafer, in particular, a normal semiconductor wafer 8 as shown in FIG. 5. It is noted that, in case the wafer apparatus 9 is a testing apparatus, the wafer apparatus 9 is used to test a normal semiconductor wafer 8, but the testing wafer 10 of the in-wafer testing device 1 of the present invention is used to test the wafer apparatus 9, and it should not be confused between the objects to be tested in this case.

The testing wafer 10 may be regarded as a dummy wafer, that is not a material to form integrated circuit (IC) chip products, which means the dummy testing wafer 10 will not undergo processes such as depositing, etching, flushing, polishing, cutting, and so on, that is used to manufacture, process, or test a normal semiconductor wafer 8, so that the testing wafer remains reusable for the next testing.

The testing circuit 20 is integrated in the testing wafer 10, and configured to measure one or more properties of the wafer apparatus 9. In particular, the one or more properties of the wafer apparatus 9 measured by the testing circuit 20 may include a position, a shift, a path, a linear velocity, a linear acceleration, an angular velocity, an angular acceleration, a vibration, a temperature, an invisible light, and/or a humidity of a unit of the wafer apparatus 9, but not limited thereto. The unit refers to a part of the wafer apparatus 9, and may be a chamber 90 or a robot arm 91 as shown in FIG. 1, or a conveyor 92, a support plate 93, or a support frame 94 as shown in FIG. 2, but not limited thereto.

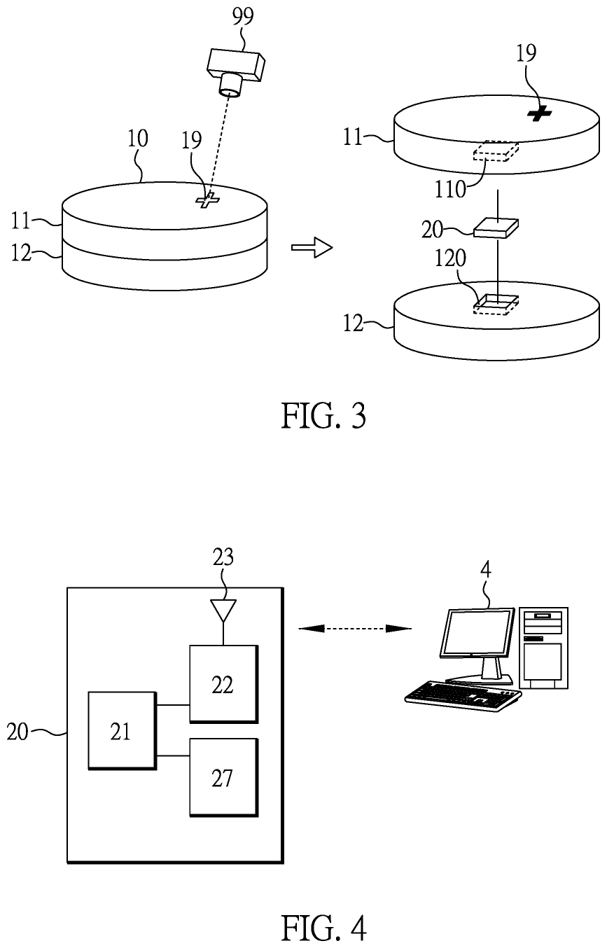

FIG. 3 shows a structural diagram of the testing wafer 10 according to one embodiment of the present invention.

The testing wafer 10 may include a top layer 11 and a bottom layer 12 in a stack, that is, they overlap each other. The testing circuit 20 may be disposed between the top layer 11 and the bottom layer 12. In particular, a top recess 110 may be formed in the top layer 11, a bottom recess 120 may be formed in the bottom layer 12, and the testing circuit 20 may be thus disposed between the top recess 110 and the bottom recess 120.

However, in another embodiment, it is also possible to form a recess in only one of the top layer 11 and the bottom layer 12 for the testing circuit 20 to be disposed therein. In still another embodiment, the testing wafer 10 may include three or more layers in a stack, wherein them are formed with recesses respectively, and different modules (the microprocessor 21, the wireless transceiver 22, the sensor 27, and so on) of the testing circuit 20 may be separately disposed into the recesses in different layers. In yet another embodiment, the testing wafer 10 is formed on a surface of the testing wafer 10 rather than inside the testing wafer 10.

FIG. 4 shows a block diagram of the testing circuit 20 according to one embodiment of the present invention.

The testing circuit 20 integrated into the testing wafer 10 includes a microprocessor 21, a wireless transceiver 22, and at least one sensor 27. The wireless transceiver 22 and the sensor 27 are both connected to and controlled by the microprocessor 21.

The microprocessor 21 is configured to perform a measurement algorithm for obtaining the one or more properties of the wafer apparatus 9. The measurement algorithm may be implemented in a form of software or hardware, and its details depend on actual applications.

The wireless transceiver 22 is configured to wirelessly communicate with a monitoring device 4 for the wafer apparatus 9. For this purpose, the wireless transceiver 22 includes an on-chip antenna 23. A staff can monitor or even control the wafer apparatus 9 by the monitoring device 4, and a testing result or the measured one or more properties come from the in-wafer testing device 1 of the present invention can be shown on the monitoring device 4.

The sensor(s) 27 may include a position sensor, an orientation sensor, or a magnetometer for detecting static properties, or it may include a motion sensor, an accelerometer, a gravity sensor, a gyroscope or a rotation vector sensor, for dynamical properties, or it may include an environmental sensor, a barometer, a photometer, or a thermometer for environmental properties, but not limited thereto.

In addition, as shown in FIG. 3, the testing wafer 10 may be formed with a marker 19 on its surface so that the testing wafer 10 is distinguishable from a normal semiconductor wafer 8. The marker 19 may be an optical marker, an electronic marker, a magnetic marker, or a physical marker (for example, a protrusion or a groove), but not limited thereto. Correspondingly, the wafer apparatus 9 may include an identifier 99, such as a camera, an antenna, or a coil, used to identify the marker 19, but not limited to.

FIG. 5 shows a schematic diagram illustrating a testing procedure using the in-wafer testing device 1 of the present invention.

The testing wafer 10 of the in-wafer testing device 1 of the present invention may have the same shape, size, volume, and/or weight as a normal semiconductor wafer 8 does, and at least a superficial portion (for example, the portion excluding the testing circuit 20) of the testing wafer 10 may be made of the same material as a normal semiconductor wafer 8 is, so that when testing wafer 10 is put near a normal semiconductor wafer 8, they looks similar in appearance.

Referring to FIG. 5, in order to perform a testing procedure according to the present invention, in step S1, a normal semiconductor wafer 8 is put into the wafer apparatus 9, and a normal operation is executed by the wafer apparatus 9 for the normal semiconductor wafer 8. The normal operation may be manufacturing, processing, testing, and so on, as previously mentioned. Until the normal operation in step S1 is finished, the normal semiconductor wafer 8 is taken out from the wafer apparatus 9.

Then, in step S2, the testing wafer 10 of the in-wafer testing device 1 of the present invention is put into the wafer apparatus 9 (in particular, its chamber 90), and a measurement by the testing circuit 20 integrated in the testing wafer 10 is performed. The measurement may include one or more properties of the wafer apparatus 9, such as a position, a shift, a path, a linear velocity, a linear acceleration, an angular velocity, an angular acceleration, a vibration, a temperature, an invisible light, and/or a humidity of a unit (for example, a chamber 90, a robot arm 91, a conveyor 92, a support plate 93, a support frame 94, and so on) of the wafer apparatus 9. Until the measurement in step S2 is finished, the testing wafer 20 is taken out from the wafer apparatus 9.

Then, in step S3, another normal semiconductor wafer 8 is put into the wafer apparatus 9, and another normal operation is executed by the wafer apparatus 9 for the other normal semiconductor wafer 8. Step S3 is usually similar to Step S1.

The testing in step S2 may be performed periodically after a number of normal operations of normal semiconductor wafers 8, or after specific time interval, such as hours or days.

It can be understood that, since the testing wafer 10 of the in-wafer testing device 1 of the present invention can have a similar appearance as well as some characteristics (shape, size, volume, weight, material, and so on) similar to a normal semiconductor wafer 8, a similar operation (moving, rotating, overturning, and so on) may be applied to the testing wafer 10 without adjusting the wafer apparatus 9.

For example, it is not necessary to turn off the wafer apparatus 9 to perform the testing, and the wafer apparatus 9 can be measured with its power supply remaining turned on. The term “turning off” in the context of the present invention means to turn off a main power supply of the wafer apparatus 9, so that when the wafer apparatus 9 restarts, it is necessary to wait some restoring processes such as heating up, cooling down, vacuuming, or purifying, again to meet with the original conditions for the normal semiconductor wafer 8. The turning off is an undesired operation, and can be avoided by the present invention.

For another example, it is not necessary to open an airtight cover (not shown) of the wafer apparatus 9 to put a detecting instrument into the wafer apparatus 9, and the wafer apparatus 9 can be measured with its chamber 90 remaining vacuumed or purified.

After being suitably shaped and sized, the in-wafer testing device 1 of the present invention may be carried and used in measuring various objects, such as an unmanned transport vehicle (UTV) on the ground or in the air, a floor traveling vehicle (FTV) including an automated guided vehicle (AGV) system or a rail guided vehicle (RGV) system, an overhead traveling vehicle (OTV) including an overhead shuttle (OHS) system or an overhead hoist transport (OHT) system. In these cases, the so-called “wafer apparatus” does not refer to a manufacturing apparatus, but refers to merely a wafer storage.

Although the present invention has been explained in relation to its preferred embodiment, it is to be understood that many other possible modifications and variations can be made without departing from the spirit and scope of the invention as hereinafter claimed.

1. An in-wafer testing device for a wafer apparatus, comprising:
a testing wafer, adapted to be put into the wafer apparatus; and
a testing circuit, integrated in the testing wafer, and configured to measure one or more properties of the wafer apparatus,
wherein the testing wafer includes a top layer and a bottom layer in a stack, and the testing circuit is disposed between the top layer and the bottom layer,
wherein a top recess is formed in the top layer, a bottom recess is formed in the bottom layer, and the testing circuit is disposed between the top recess and the bottom recess.

2. The in-wafer testing device of claim 1, wherein the wafer apparatus is a manufacturing apparatus, a processing apparatus, or a testing apparatus, for a semiconductor wafer.

3. The in-wafer testing device of claim 1, wherein the testing wafer is a dummy wafer that is not a material to form chip products.

4. The in-wafer testing device of claim 1, wherein the wafer apparatus is measured with its power supply remaining turned on.

5. The in-wafer testing device of claim 1, wherein the wafer apparatus is measured with its chamber remaining vacuumed or purified.

6. (canceled)

7. The in-wafer testing device of claim 1, wherein a measurement by the testing circuit in the testing wafer is performed after a normal operation executed by the wafer apparatus for a normal semiconductor wafer and before another normal operation executed by the wafer apparatus for another normal semiconductor wafer.

8. The in-wafer testing device of claim 1, wherein the one or more properties of the wafer apparatus measured by the testing circuit include a position, a shift, a path, a linear velocity, a linear acceleration, an angular velocity, an angular acceleration, a vibration, a temperature, an invisible light, and/or a humidity of a unit of the wafer apparatus.

9. The in-wafer testing device of claim 8, wherein the unit is a robot arm, a conveyor, a support plate, a support frame, or a chamber of the wafer apparatus.

10. The in-wafer testing device of claim 1, wherein the testing circuit includes a microprocessor configured to perform a measurement algorithm for obtaining the one or more properties of the wafer apparatus.

11. The in-wafer testing device of claim 8, wherein the testing circuit includes a wireless transceiver connected to the microprocessor, and the wireless transceiver is configured to communicate with a monitoring device for the wafer apparatus.

12. The in-wafer testing device of claim 11, wherein the wireless transceiver includes an on-chip antenna.

13. The in-wafer testing device of claim 1, wherein the testing circuit includes a position sensor, an orientation sensor, or a magnetometer, connected to the microprocessor.

14. The in-wafer testing device of claim 1, wherein the testing circuit includes a motion sensor, an accelerometer, a gravity sensor, a gyroscope or a rotation vector sensor, connected to the microprocessor.

15. The in-wafer testing device of claim 1, wherein the testing circuit includes an environmental sensor, a barometer, a photometer, or a thermometer, connected to the microprocessor.

16-17. (canceled)

18. The in-wafer testing device of claim 1, wherein the testing wafer is formed with an optical marker, an electronic marker, a magnetic marker, or a physical marker on its surface so that the testing wafer is distinguishable from a normal semiconductor wafer.

19. The in-wafer testing device of claim 18, wherein the wafer apparatus includes an identifier used to identify the marker(s).

20. The in-wafer testing device of claim 1, wherein the wafer apparatus is implemented as an unmanned transport vehicle (UTV), a floor traveling vehicle (FTV) including an automated guided vehicle (AGV) system or a rail guided vehicle (RGV) system, an overhead traveling vehicle (OTV) including an overhead shuttle (OHS) system or an overhead hoist transport (OHT) system.
